(19) United States
(12) Patent Application Publication
(10) Pub. No.: US 2008/0302656 A1
(43) Pub. Date: Dec. 11, 2008

(54) VACUUM COATING INSTALLATION WITH TRANSPORT ROLLERS FOR THE TRANSPORT OF A PLANAR SUBSTRATE

(76) Inventors: Jurgen Henrich, Limeshain (DE); Andreas Sauer, Grossostheim (DE); Harald Wurster, Mombris (DE); Edgar Haberkorn, Jossgrund (DE)

Correspondence Address: COOLEY GODWARD KRONISH LLP;ATTN: Patent Group, Suite 1100, 777 - 6th Street, NW, WASHINGTON, DC, 20001, US

(21) Appl. No.: 11/758,955

(22) Filed: Jun. 6, 2007

(51) Int. Cl. C23C 14/34

(52) U.S. Cl. 204/298.23

(57) ABSTRACT

The invention relates to a vacuum coating installation with a transport system for planar substrates which are transported through a vacuum chamber. This transport system comprises several cylinders disposed in parallel. As the driving means for these cylinders one or several motors may be provided, which are located within or outside of the vacuum chamber. The coupling between the motor or the motors and the cylinders in any event takes place via magnet couplings. Since hereby no mechanical coupling established between the driving means and the cylinders, these can readily be separated from one another, which permits providing the cylinders, and with them the sputter cathodes, in a slide-in element which can be moved into and out of the vacuum chamber. If not every cylinder is provided with its own driving means, the cylinders, which are coupled with a driving means, can be connected via V-belts or the like with the other cylinders.

### PRIORITY

The present application claims priority from to commonly owned and assigned European Application No. 06 012 805.5/EP 06012805, entitled Vacuum Coating Installation with Transport Rollers for the Transport of a Planar Substrate, which is incorporated herein by reference.

### FIELD OF THE INVENTION

The present invention relates to vacuum coating installations.

### BACKGROUND OF THE INVENTION

The coating of substrates in vacuum coating installations takes place thereby that particles are knocked out of a target, which are moved in the direction toward the substrate and are deposited thereon. To obtain uniform coating of the substrate, substrate and target perform a relative movement with respect to one another, with the substrate preferably being moved past the target.

The substrate is therein moved by means of a special transport device.

If a large-area and substantially rigid substrate, for example architectural glass, is to be coated, a transport system is frequently utilized, which is comprised of different sequential transport rollers. These transport rollers are connected with one another via toothed belts, chains or toothed wheels and driven by means of a common driving means, for example by means of a motor.

A driving device for a shaft is already known, which is located in a chamber (US 2005/0206260 A1). This shaft is here operated via a magnet coupling by means of a motor, the motor being located outside of the chamber.

A transport device for substrates in vacuum coating installations with several rollers is moreover known, at least one roller serving as a driving shaft (DE 103 28 273 A1). In this device the driving means as well as the transport rollers are all located in the evacuated area of the coating installation.

Lastly, a process chamber is also known which comprises a transport system for workpieces (GB 2 171 119 A). This transport system includes cylinders driven by a magnet coupling. The magnet coupling serves herein not only for the torque transmission from the outside into the process chamber, but also for switching between two sets of transport rollers disposed on a lift within the chamber.

Although present devices are functional, they are not sufficiently accurate or otherwise satisfactory. Accordingly, a system and method are needed to address the shortfalls of present technology and to provide other new and innovative features.

### SUMMARY OF THE INVENTION

Exemplary embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents and alternative constructions that fall within the spirit and scope of the invention as expressed in the claims.

The invention relates to a vacuum coating installation with a transport system for planar substrates which are transported through a vacuum chamber. This transport system comprises several cylinders disposed in parallel. As the driving means for these cylinders one or several motors may be provided, which are located within or outside of the vacuum chamber. The coupling between the motor or the motors and the cylinders in any event takes place via magnet couplings. Since hereby no mechanical coupling established between the driving means and the cylinders, these can readily be separated from one another, which permits providing the cylinders, and with them the sputter cathodes, in a slide-in element which can be moved into and out of the vacuum chamber. If not every cylinder is provided with its own driving means, the cylinders, which are coupled with a driving means, can be connected via V-belts or the like with the other cylinders.

As previously stated, the above-described embodiments and implementations are for illustration purposes only. Numerous other embodiments, implementations, and details of the invention are easily recognized by those of skill in the art from the following descriptions and claims.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying Drawings wherein:

FIG. 1 depicts a perspective representation of a segment of a vacuum coating installation with a transport device.

FIG. 2 depicts a view A onto the vacuum coating installation according to FIG. 1.

FIG. 3 depicts an enlarged partial segment of the vacuum coating installation depicted in FIG. 2.

FIG. 4a-c depicts the process of removing a slide-in element of the vacuum coating installation depicted in FIG. 2.

FIG. 5 depicts a segment of the vacuum coating installation depicted in FIG. 4a to 4c after its rotation by 90° in the counterclockwise direction.

FIG. 6 depicts a perspective view of a slide-in element.

FIG. 7 depicts a perspective view of the slide-in element depicted in FIG. 5 after its rotation by 180°.

### DETAILED DESCRIPTION

The present invention addresses the problem of providing a transport device for a planar substrate in vacuum coating installations, wherein the installing and uninstalling of this transport device into and from the vacuum coating installation can be accomplished without great difficulties.

The invention consequently relates to a vacuum coating installation with a transport system for planar substrates being transported through a vacuum chamber. This transport system comprises several parallel disposed cylinders. As the driving means for these cylinders one or several motors may be provided which are located within or outside of the vacuum chamber. The coupling between the motor(s) and the cylinders in every case takes place via magnet couplings. Since hereby no mechanical coupling between the driving means and the cylinders is necessary, they can readily be separated from one another, which permits providing the cylinders, and with them the sputter cathodes, in a slide-in element, which can be driven into and out of the vacuum chamber. If not every cylinder is provided with its own driving means, the cylinders which are coupled with a driving means, can be connected via V-belts or the like with the other cylinders.

The advantage attained with the invention comprises in particular that rotating sealing elements, for example rotary shaft seals or fluid seals are not required. In addition, potential leakage sites are avoided. Magnet couplings are moreover contact-free and therewith wear- and maintenance-free: they can also be produced more cost-effectively than rotary feedthroughs. Added to this is that in the case of magnet couplings a torque limitation can be set in simple manner via the magnet distance.

If the transport device involves one such provided with transport rollers for the transport of large-area substrates, such as for example sheets or glass, in particular architectural glass, it is especially advantageous if each of the transport rollers includes its own magnet gap coupling. Compared to rotationally robust couplings, the magnet gap couplings have in particular the advantage that they are vacuum-tight. This property makes them virtually ideal for use in vacuum coating installations. Of advantage is also that the magnet gap couplings can be implemented as radial and axial types of construction.

Thus the driving mechanics can not only be located in the vacuum, as is conventional, but also under atmospheric pressure.

Thereby that the driving mechanics are located at atmospheric pressure, maintenance and repairs are less complicated, since the long evacuation times of several hours become unnecessary, whereby the production costs are markedly reduced. If the driving mechanics are placed at atmospheric pressure, this means furthermore that the relatively expensive vacuum rotary feedthroughs are no longer required. They are replaced by the much more cost-effective magnet gap couplings. By utilizing the magnet gap couplings therefore rotary sealing elements, such as for example shaft or fluid sealings, no longer need to be installed, whereby potential leakage sites are avoided.

Since the driving means, for example an electric motor, transmits the rotary movement via the magnet gap coupling onto the transport rollers, the transport rate of the substrate can also be set simply. For one, the transport rate can be set via the driving means itself; for another, via the distance of the magnets from one another, a torque limitation can be obtained, wherein the strength of the magnets also has a decisive influence on the torque.

The transport rollers must be removed for regular cleaning, which can be readily realized in the case of the invented transport rollers, for the connection between the part to be uninstalled and the driving means can be readily detached, i.e. the uninstalling of the transport rollers can be accomplished without major expenditures. Reinstalling can also be readily realized, in contrast to the coating devices with rotary feedthroughs.

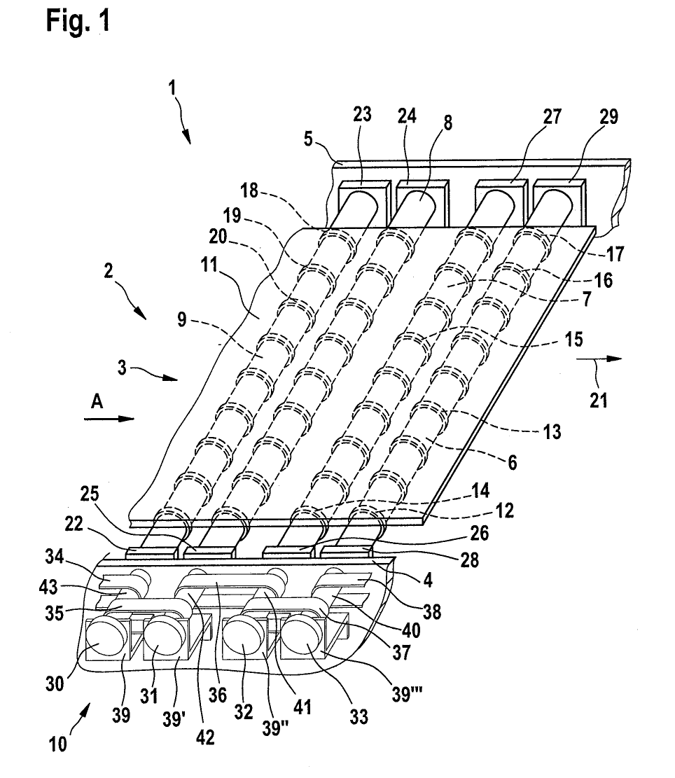

FIG. 1 shows a perspective view of a segment of a vacuum coating chamber 2 in a vacuum coating installation 1. Seen are subregions of two opposing walls 4, 5 delimiting the vacuum coating chamber 2. In the vacuum coating chamber 2 is located a transport device 3, which comprises several transport rollers 6, 7, 8, 9 extending in parallel. These transport rollers 6 to 9 are driven via a driving system 10 sitting outside of the vacuum coating chamber 2. With the aid of this driving system 10 the transport rollers 6 to 9 execute a rotary movement about their own longitudinal axis. On the transport rollers 6 to 9 is located a substrate 11 which is to be coated. The substrate is herein a planar substrate, for example architectural glass. In order for the substrate 11 not to rest directly on the transport rollers 6 to 9, on the outsides of the transport rollers 6 to 9 can be applied for example a rubber-type elastic material. This serves for the purpose of preventing the substrate 11 from becoming scratched, which is important precisely when the substrate is glass.

As depicted in FIG. 1, the rubber-type elastic material may be disposed in the form of rings 12 to 20 on the transport rollers 6 to 9. However, it may also assume a different form and be implemented, for example, in the form of knobs. Through the movement of the transport rollers 6 to 9, the substrate 11 disposed on them is also moved.

Each transport roller 6 to 9 is disposed between two bearings 22, 23; 24, 25; 26, 27; 28, 29, which ensure the rotation of the transport rollers 6 to 9 about their own axis. However, transport rollers clamped in at one side are also realizable.

The transport rollers 6 to 9 are connected with the driving system 10, which may include several individual driving means, for example motors 30 to 33. These motors 30 to 33 are coupled with the ends of axles 40 to 43. With the aid of motors 30 to 33 the transport rollers 6 to 9 can be individually driven via the axle 40 and the magnet couplings not evident in FIG. 1.

In the embodiment example according to FIG. 1, however, a single motor, for example 30, would suffice for driving all transport rollers 6 to 9, since the axle 43 also drives axle 42 via a toothed belt 35 and the axle 42, in turn, drives the axle 41 via a toothed belt 36, etc. Since all axles 40 to 43 are coupled via toothed belts 34 to 38 with each adjacent axle, consequently only one motor is sufficient.

If the toothed belts 34 to 38 are omitted, each axle 40 to 43 can be driven via its own motor 30 to 33.

Axles 40 to 43 rest on supports 39 to 39′″ which are connected with a wall 4.

Independent of whether one motor or several motors are utilized, the goal is the uniform rotation of all transport rollers 6 to 9.

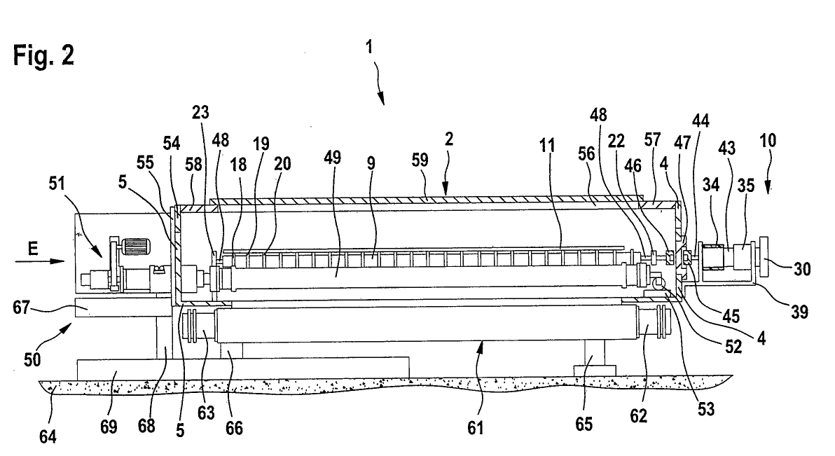

The magnet couplings not evident in FIG. 1 are substantially located in the wall 4. One of these magnet couplings is depicted in FIG. 2.

FIG. 2 shows a view A onto the vacuum coating installation 1 according to FIG. 1. This sectional view shows a portion of the driving system 10 with the motor 30 and the axle 43 on which the chains or the belts 34, 35 are disposed. Axle 43, at whose end the motor 30 is flanged on, is in contact on support 39, Support 39 is connected with the wall 4 of the vacuum coating chamber 2 and serves for stabilizing and bracing axle 43 and motor 30. Axle 43 connected with motor 30 has a rod-form extension 44, at whose end a magnet 45 is disposed.

This magnet 45 is opposed by a further magnet 46 located in the vacuum coating chamber 2. Both magnets 45, 46 are separated by a cup-form top structure 47, the cup-form top structure 47 forming a portion of wall 4 of the vacuum coating chamber 2. This top structure 47 is comprised of a non-magnetizable or non-magnetic material, which ensures that the magnets 45, 46 can exert mutual magnetic influence.

Magnet 46 is disposed at one end of a rod-form axle 48, which is connected with the transport roller 9. The axle 48 with the transport roller 9 disposed thereon is disposed between the two opposite bearings 22, 23 which hold the transport roller 9. The transport roller 9 includes several rings 18 to 20, preferably comprised of rubber-type elastic material, on which the substrate 11 rests.

Evident is also a tubular cathode 49, which is disposed slightly beneath the transport roller 9. The cathode is located between two adjacent transport rollers, such that substrate 11 is coated from below. However, it is also possible to coat the substrate from above by applying cathodes above the substrate 11.

As shown in FIG. 2, this cathode is a round tube cathode 49, which is in connection with a driving chamber 50 located outside of the vacuum coating chamber 2. In this driving chamber 50 is located a driving means 51, via which the round tube cathode 49 is driven. It therein rotates about the longitudinal axis, whereby the uniform coating of the substrate 11 is attained.

This round tube cathode 49 is a conventional round tube cathode with a target disposed on it, such as is described for example in DE 196 51 378 A1.

While the round tube cathode 49 is connected at its one end with the driving means 51 located in the driving chamber 50, it rests with its other end on a roller 52. This rotatable roller 52, in turn, rests on a bearing track 53.

In the state in which the slide-in element E is installed, the roller or cylinder 52 is located in the proximity of the wall 4. A further, not depicted, roller or cylinder of the slide-in element E is in the proximity of wall 5 when the slide-in element is installed in the vacuum chamber. In contrast to the depiction in FIG. 2, the bearing track 53 extends preferably over the entire width of the vacuum chamber. Proximal to wall 5, this bearing track 53 is provided with a stop. The carrier element 69 of slide-in element E extends substantially over the entire width of the vacuum chamber 2. It also encompasses a footing 65.

On the side of the driving system 10 for the transport rollers 6 to 9 the vacuum coating chamber 2 includes wall 4 with the cup-like top structure 47 embedded in it. The side opposing wall 4 is comprised of a wall of two wall regions, a lower wall region 5 and an upper wall region 54. These two wall regions 5, 54 can be separated from one another and, when the vacuum coating installation 1 is in operation, they are connected via a flange 55. The vacuum coating chamber 2 has an upper opening 56, encompassed by two flanges 57, 58 disposed at walls 4 and 54, and is closed by means of a cover 59.

The vacuum coating installation 1, in addition, comprises a pump system 61 including two pumps 62, 63.

By means of this pump system 61, the vacuum coating chamber 2 can be evacuated. The vacuum coating chamber 2 as well as the pump system 61 rest on several pedestals on a level surface 64. Of these pedestals only pedestal 65 and 66 are evident in FIG. 2.

The driving chamber 50 is disposed on a frame 67, 68 which rests on a carrier element 69.

The frame 67, 68 of carrier element 69 as well as the driving chamber 50 form therein a unit. Directly connected with the driving chamber 50 are the wall 5 as well as the round tube cathode 49 and the transport roller 9. Together they form the slide-in element E. This slide-in element E can be removed from the vacuum coating installation 1 without the entire vacuum coating chamber 2 (cf. European Patent Application EP 1 698 715) having to be dismantled.

The transport rollers 6 to 9 can thereby be cleaned readily and conveniently which saves time and money. During the cleaning another slide-in element can be slid into the vacuum coating chamber 2 and mounted. Consequently, the vacuum coating installation 1 can rapidly be taken into operation again, which saves expenditures.

Although the vacuum coating chamber according to FIG. 2 has only been described with a round tube cathode 49, it is understood that the use of planar targets is also possible. Thus, for example a planar target may be disposed above the substrate 11, the substrate 11 being moved past the target in the described manner.

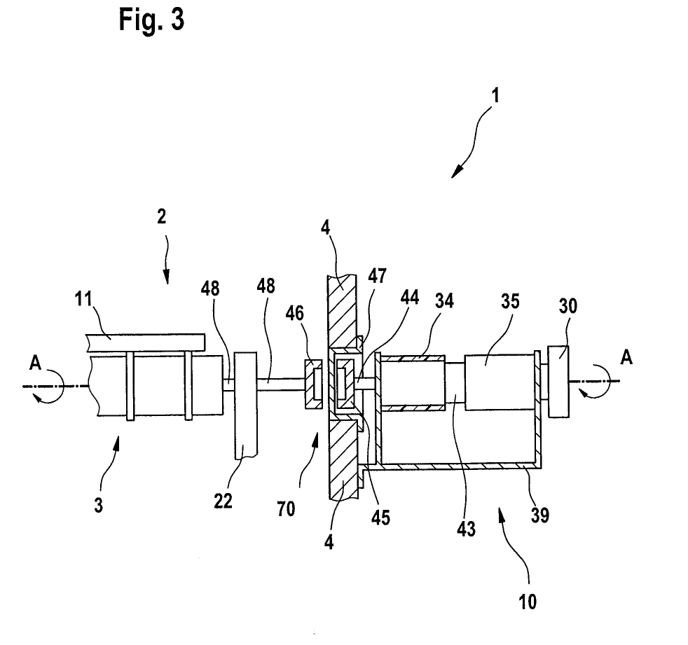

FIG. 3 shows an enlarged partial segment of the right side of the vacuum coating installation 1 depicted in FIG. 2. A portion of the driving system 10 with the axle 43 attached on support 39, at whose end the motor 30 is disposed, is evident.

In the direction toward wall 4 of the vacuum coating chamber 2 the axle 43 has a rod-form extension 44, at whose end magnet 45 is located, which has a north and a south pole. Opposite this magnet 45 is located a further equally structured magnet 46. Between the two magnets 45, 46 a cup-form top structure 47 is provided. Magnets 45, 46 and the cup-like top structure 47 together form a so-called magnet gap coupling 70. The cup-like top structure 47 is therein comprised of a material which is not magnetizable and not magnetic, this top structure 47 being embedded vacuum-tight in wall 4.

If the axle 43 of the driving system 10 is moved via motor 30, the axle 43 executes a movement about A-A. Therewith the magnet 45 located at the rod-form extension 44 of axle 43 is set into rotational motion.

Since the top structure 47 is comprised of a non-magnetizable material, for example of aluminum or quartz, the rotational movement of magnet 45 is transmitted to magnet 46. Since this magnet 46 is connected via an axle 48 with the transport roller 9, the rotational movement is also transmitted to the transport roller 9 which now moves about its longitudinal axis and therewith also transports the substrate 11 located on it.

One advantage of the magnet gap coupling 70 lies therein that no rotary sealing element, such as for example a shaft seal or a fluid seal, is required. Thereby that these sealing elements, which are prone to failure, no longer need to be installed, potential leakage sites in the vacuum coating chamber 2 can be avoided.

The magnet gap couplings are also more cost-effective in production, free of wear and very simple to maintain. The technically highly complicated and expensive rotary feedthroughs can consequently be omitted. The magnet gap couplings are rotationally robust and, moreover, vacuum-tight.

If the transport rollers 6 to 9 are connected with a driving system 10 via magnet gap couplings 70, a transport roller 6 to 9 can be decoupled free of contact by simply removing it.

Via the distance of the magnets 45, 46 or the field strength of magnets 45, 46 a torque limitation can be set in simple manner. Further, shaft offsets can be compensated without additional structural elements.

As is evident in FIG. 3, the driving system 10 is located outside of the vacuum coating chamber 2. However, a variant is also conceivable, in which the driving system 10 is located in the vacuum coating chamber 2. In this variant of a simple magnet coupling, which is also highly rotationally robust, a cup-form top structure 47 is no longer necessary.

If the magnet couplings 70 are disposed within the vacuum coating chamber 2, axles 40 to 43 with belts 34 to 38 can also be disposed in the vacuum coating chamber 2. In this case these structural parts remain always in the vacuum coating chamber 2 so that they cannot become misaligned. Axles 40 to 43 with belts 34 to 38 are in this case driven via a single rotary feedthrough or magnet coupling by a motor located outside of vacuum coating chamber 2. It would be feasible to provide the motor also in the vacuum coating chamber 2.

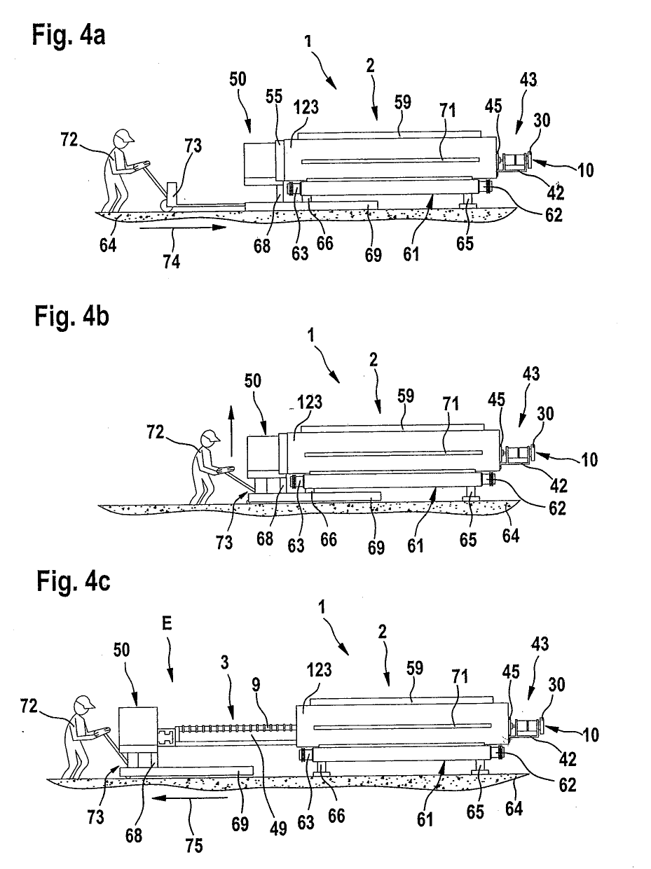

FIG. 4a to 4c show the process of removal of the slide-in element E from the vacuum coating installation 1 depicted in FIG. 2. The vacuum coating chamber 2 with the pump system 61 disposed thereon comprises pedestals 65, 66 which stand on the bottom 64. The vacuum coating chamber 2, in addition, is provided on the long side with a slot-form opening 71, which is set into wall 21 of the vacuum coating chamber 2. Through this opening 71 the substrate 11 is fed into the vacuum coating chamber 2 without this process having any negative effects on the vacuum obtaining in the vacuum coating chamber 2.

In FIG. 4a a person 72 moves a fork-lift carriage 73 in the direction of arrow 74, i.e. under the driving chamber 50.

In FIG. 4b the fork-lift carriage 73 is located under the vacuum coating installation 2, whereby the entire slide-in element E can be readily lifted and, according to FIG. 4c, removed from the vacuum coating installation 1 in the direction of arrow 75. This easy lifting leads to the raising of the roller, not shown in FIG. 2, near the wall 5 over a stop and thus the removal can be started. The slide-in element E now rests, on the one hand, on fork-lift carriage 73 and, on the other hand, on roller 52. In this way the slide-in element E can be pulled out until the roller 52 runs against the stop near the wall 5. In order to move this roller 52 also over the stop, a flap bridge is moved from its horizontal position into a vertical position in which it braces that end of slide-in element E, at which the roller 52 is disposed. The not shown flap bridge is therein to be disposed on the carrier elements 69, 69′ such that in the state of the slide-in element E, in which it is nearly moved out and the roller 52 lies on the stop near the wall 5, in the perpendicular state braces a region of slide-in element E, which at this time is already outside of the vacuum chamber. Without this supporting flap bridge and with the slide-in element E uninstalled, the load on frame 68 would be too high due to the very long free cantilever.

After removing the slide-in element E, it can be exchanged against another one without the coating process needing to be interrupted for any length of time.

The slide-in element E can now be readily cleaned or the target be removed from the round tube cathode 49 and be replaced by a new one.

However, the slide-in element E can alternatively also be moved on rollers, on an air cushion, on rails or on a similar device.

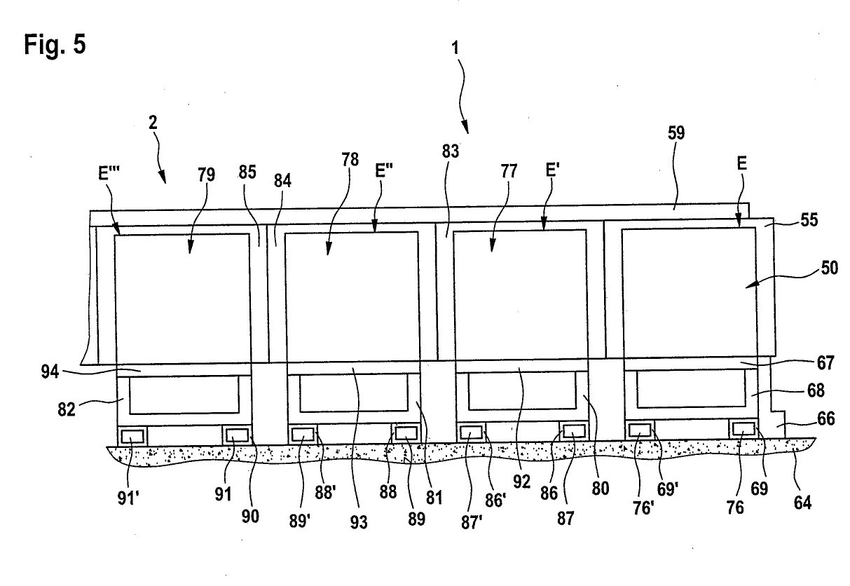

FIG. 5 shows a segment of the vacuum coating installation 1 depicted in FIG. 4a to 4c, after rotation by 90″ in the clockwise direction. A person with fork-lift carriage is not depicted for the sake of clarity.

Evident are the driving chambers 50, 77 to 79 disposed one next to the other at a defined distance with respect to each other and which are connected via a frame 67, 68; 80, 92; 81, 93; 82, 94 with two base elements 69, 69′; 86, 86′; 88, 88′; 90, 90′. Each of these base elements has openings 76, 76′; 87, 87′; 89, 89′; 91, 91′ into which the forks of a fork-lift carriage can be introduced. Each of the driving chambers 50, 77 to 79 locks off the vacuum coating chamber 2 by means of flanges 55, 83 to 85. The slide-in elements E to E′″ can be removed individually from the vacuum coating installation 1 and be maintained.

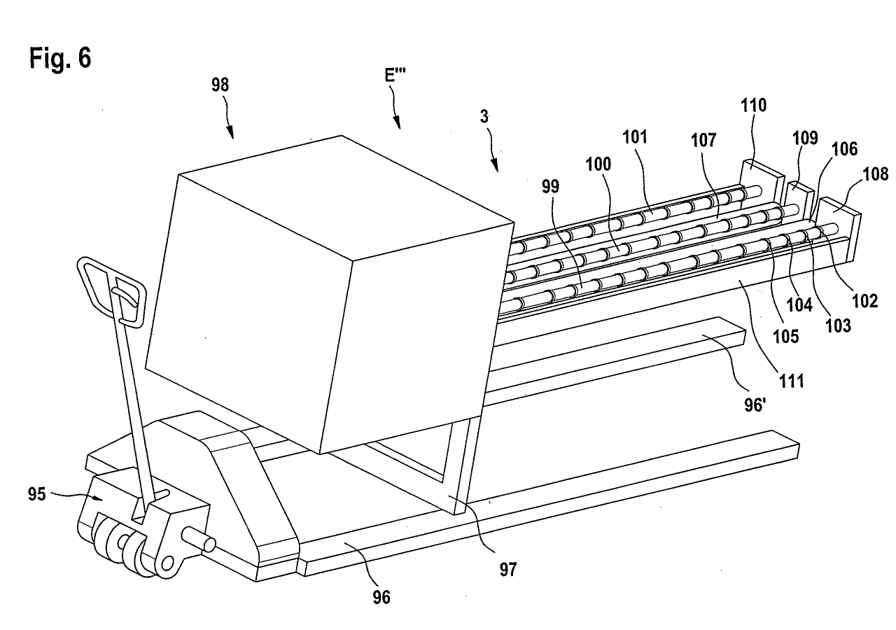

FIG. 6 shows a perspective view of a slide-in element E′″ which has been pulled out of a vacuum coating installation by means of the fork-lift carriage 95.

The slide-in element E′″ comprises two base elements 96, 96′ into which the forks of the fork-lift carriage 95 have been slid. On the base elements 96, 96′ is disposed a U-form frame 97, on which a driving chamber 98 is located. The functions of base elements 96, 96′ correspond to the carrier element 69 in FIG. 2. The forks of fork-lift carriage 95 can run between the two lower base elements 96, 96′ of slide-in element E. However, they can also run into these base elements, if these base elements are comprised, for example, of U-profiles open in the downward direction. When the slide-in element E′″ is not installed in the installation, the base elements 96, 96′ float slightly above the bottom.

The slide-in element E′″ includes several transport rollers 99 to 101, which are provided with rings 102 to 105 preferably comprised of a rubber-type elastic material. Beneath the transport rollers 99 to 101 are located two round tube cathodes 106, 107, each of the round tube cathodes 106, 107 being located between two adjacent transport rollers 99, 100; 100, 101.

The transport rollers 99 to 101 are disposed between pedestals, only pedestals 108 to 110 being visible. The opposing pedestals of slide-in element E′″ are connected with one another with side bars, of which in FIG. 6 only a side bar 111 is visible.

If a slide-in element E is uninstalled, an easily detachable connection between the short shafts 40 to 43 with belts 35 to 38 (cf. FIG. 1) and the transport rollers 6 to 9 proper is necessary. This easily detachable connection is accomplished in the embodiments, in which all driving parts are located in the vacuum chamber, through the magnet couplings, which in this case are located in the vacuum chamber. In this embodiment the number of cup-form elements and membranes is reduced, however the number of structural elements in the vacuum chamber is not increased.

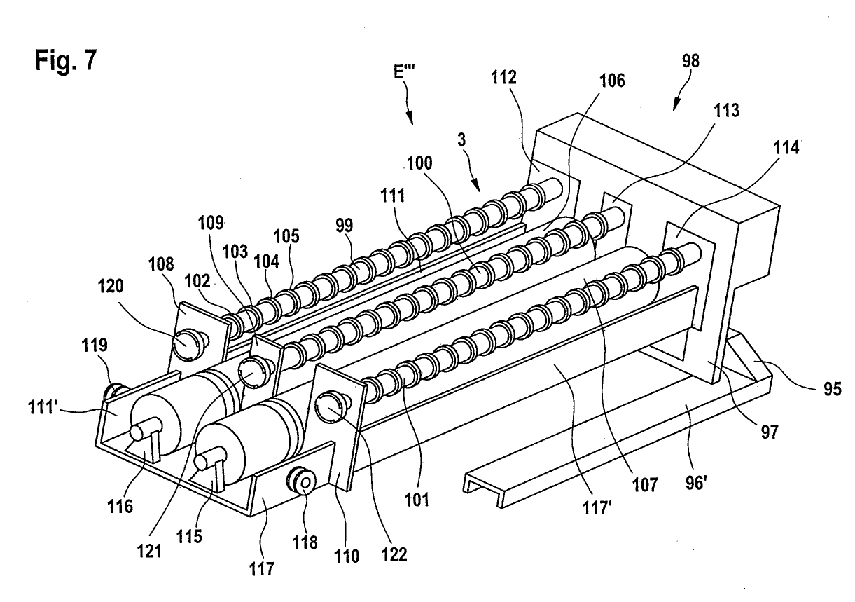

FIG. 7 shows a perspective view of the slide-in element E′″, depicted in FIG. 6, after a rotation about 180°. The manner in which each of the transport rollers 99 to 101 is disposed between two pedestals 108,112; 109,113; 110, 114 is now evident. At the ends pointing toward the viewer of the transport rollers 99 to 101 magnets 120 to 122 can be seen. These magnets 120 to 122 are each a part of a magnet coupling or of a magnet gap coupling of a vacuum coating installation.

The round tube cathodes 106, 107 are each disposed between the transport rollers 99, 100 and 100, 101, respectively, on mountings 115, 116; they are connected with the driving chamber 98.

Evident are also the side bars 111, 117, which are located between the pedestals 108, 112 and 110, 114, respectively. These side bars 111, 117 include each an elongated end 111′, 117′, on which one roller 118, 119 each is disposed. These rollers 118, 119 facilitate considerably the uninstalling and reinstalling of the slide-in element E′″, especially if the vacuum coating installation includes guides such as are depicted in FIG. 2.

The guide may additionally include a snap-in mechanism. When the roller 118, 119 reaches the guide intended for it, it snaps in. The slide-in element E′″ is therein oriented such that its magnets 120 to 122 are correctly seated in the magnet coupling or the magnet gap coupling.

Thereby that magnet couplings are utilized, the slide-in element E′″ can be moved out of the vacuum coating chamber 2 without mechanical dismantling.

In conclusion, the present invention provides, among other things, a system and method for vacuum coating. Those skilled in the art can readily recognize that numerous variations and substitutions may be made in the invention, its use and its configuration to achieve substantially the same results as achieved by the embodiments described herein. Accordingly, there is no intention to limit the invention to the disclosed exemplary forms. Many variations, modifications and alternative constructions fall within the scope and spirit of the disclosed invention as expressed in the claims.

What is claimed is:

1. Vacuum coating installation comprising
a vacuum coating chamber,
several rotatable transport rollers disposed in parallel within the vacuum coating chamber for the transport of a planar substrate, characterized by:
a driving means disposed outside of the vacuum coating installation
at least one magnet coupling between the driving means and at least one transport roller.

2. Vacuum coating installation comprising
a vacuum coating chamber
several rotatable cylinders disposed in parallel and within the vacuum coating chamber for the transport of a planar substrate, characterized by:
a driving means disposed within the vacuum coating chamber,
at least one magnet coupling between the driving means and at least one transport roller.

3. Vacuum coating installation as claimed in claims 1 or 2, characterized in that the at least one transport roller is coupled with the other transport rollers via belts.

4. Vacuum coating installation as claimed in claims 1 or 2, characterized in that each cylinder is coupled with its own driving means via its own magnet coupling.

5. Vacuum coating installation as claimed in claim 1, characterized in that in one wall of the vacuum coating chamber a cup-form top structure is embedded comprised of a non-magnetic and non-magnetizable material, which separates at least one magnet located in the vacuum coating chamber from at least one magnet located outside of the vacuum coating chamber.

6. Vacuum coating installation as claimed in one of claims 1 or 2, characterized in that
the cylinders are at least partially encompassed by rubber-type elastic material

7. Vacuum coating installation as claimed in claims 1 or 2, characterized in that between the cylinders sputter electrodes are disposed.

8. Vacuum coating installation as claimed in claim 2, characterized in that the cylinders and the at least one magnet coupling are part of a slide-in element which can be moved into and out of the vacuum coating chamber.

9. Vacuum coating installation as claimed in claim 1, characterized in that the cylinders
are part of a slide-in element which can be moved into and out of the vacuum coating chamber, the driving means for the cylinders remaining outside of the vacuum coating chamber.

10. Vacuum coating installation as claimed in claims 7, 8 and 9, characterized in that the
sputter electrodes are part of the slide-in element.

11. Vacuum coating installation as claimed in claims 1 or 2, characterized in that the cylinders are connected via axles with the magnet couplings which establish a connection to the driving means.

12. Vacuum coating installation as claimed in claim 11, characterized in that between the axles and the cylinders magnet couplings are provided.

13. Vacuum coating installation as claimed in claim 8 or claim 9, characterized in that
the slide-in element includes a frame which can be lifted by means of a fork-lift carriage.

14. Vacuum coating installation as claimed in claim 8 or claim 9, characterized in that a chamber including a driving means for sputter cathodes is part of the slide-in element.
